(19) United States
(12) Patent Application Publication
(10) Pub. No.: US 2026/0033267 A1
(43) Pub. Date: Jan. 29, 2026

(54) SEMICONDUCTOR CHIP, SEMICONDUCTOR PACKAGE, AND METHODS OF MANUFACTURING THE SAME

(71) Applicant: Samsung Electronics Co., Ltd., Suwon-si (KR)

(72) Inventor: Kwangyong Lee, Suwon-si (KR)

(21) Appl. No.: 19/063,873

(22) Filed: Feb. 26, 2025

(30) Foreign Application Priority Data
Jul. 25, 2024 (KR) 10-2024-0098914

(51) Int. Cl. H01L 21/78

(52) U.S. Cl. CPC H01L 21/78

(57) ABSTRACT

A method of manufacturing a semiconductor package includes forming a laser groove at a predetermined depth from a front surface of a semiconductor wafer in a cutting area of the semiconductor wafer, performing ashing on the laser groove and removing a heat affected zone, and dividing the semiconductor wafer into individual semiconductor chips by stretching the semiconductor wafer. The laser groove includes two side surfaces angled from the front surface of the semiconductor wafer and opposing each other, and an intersection of the two side surfaces at a lower end of the laser groove forms a tip.

### CROSS-REFERENCE TO RELATED APPLICATION(S)

This application claims the benefit under 35 USC 119 (a) of Korean Patent Application No. 10-2024-0098914 filed on Jul. 25, 2024 in the Korean Intellectual Property Office, the entire disclosure of which is incorporated herein by reference for all purposes.

### BACKGROUND

The present inventive concept relates to a semiconductor chip, a semiconductor package including the semiconductor chip, and methods of manufacturing the semiconductor chip and the semiconductor package.

After forming integrated circuits on an active surface of a semiconductor substrate, an inactive surface of the semiconductor substrate may be polished, and the polished semiconductor substrate may be cut to separate the integrated circuits into individual semiconductor chips. In general, the polished semiconductor substrate may be mechanically cut using a sawing blade or may be cut using a laser grooving method. When mechanical cutting is performed, the cut surfaces of the semiconductor chips may be broken, and when the laser grooving method is used, a heat affected zone HAZ may be generated due to the laser process, which reduces chip strength and causes many defects such as cracks occurring through interfaces between different materials having a low adhesive strength between them.

### SUMMARY

Example embodiments provide a semiconductor chip and a semiconductor package having improved reliability.

According to some example embodiments, a method of manufacturing a semiconductor package includes forming a laser groove at a predetermined depth from a front surface of a semiconductor wafer in a cutting area of the semiconductor wafer; performing ashing on the laser groove and removing a heat affected zone; and dividing the semiconductor wafer into individual semiconductor chips by stretching the semiconductor wafer. The laser groove includes two side surfaces angled from the front surface of the semiconductor wafer and opposing each other, and an intersection of the two side surfaces at a lower end of the laser groove forms a tip.

According to some example embodiments, a method of manufacturing a semiconductor package includes attaching a protective film to a front surface of a semiconductor wafer, and reducing a thickness of the semiconductor wafer by grinding a back surface of the semiconductor wafer; removing the protective film from the front surface of the semiconductor wafer, and forming a laser groove at a predetermined depth from the front surface in a cutting area of the semiconductor wafer; performing ashing on the laser groove and removing a heat affected zone; and dividing the semiconductor wafer into individual semiconductor chips by extending the semiconductor wafer. The laser groove includes two side surfaces extending from the front surface of the semiconductor wafer and opposing each other, and an intersection of the two side surfaces at a lower end of the laser groove forms a tip.

According to some example embodiments, a method of manufacturing a semiconductor package includes forming a semiconductor wafer by forming a device layer on a semiconductor substrate; forming a laser groove from a front surface of the device layer to a predetermined depth of the semiconductor substrate in a cutting area of the semiconductor wafer; performing ashing on the laser groove and removing a heat affected zone; and dividing the semiconductor wafer into individual semiconductor chips by stretching the semiconductor wafer, wherein the laser groove includes two side surfaces angled from the front surface of the device layer and opposing each other, and an intersection of the two side surfaces at a lower end of the laser groove forms a tip.

According to some example embodiments, a semiconductor chip includes a semiconductor substrate; and a device layer on the semiconductor substrate. The device layer includes an upper surface, a lower surface, and a side surface inclined with respect to and positioned between the upper surface and the lower surface, the semiconductor substrate includes an upper surface, a lower surface, and a side surface between the upper surface and the lower surface, the side surface includes a first side surface and a second side surface extending from the first side surface such that the side surface of the semiconductor substrate is bent at a position where the first side surface and the second side surface connect each other, and a height of the second side surface is less than a sum of a height of the device layer and a height of the first side surface.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a perspective view illustrating a semiconductor chip according to various embodiments;

FIG. 2 is a side cross-sectional view illustrating the semiconductor chip of FIG. 1;

FIG. 3 is a perspective view illustrating a semiconductor chip according to various embodiments;

FIG. 4 is a side cross-sectional view illustrating the semiconductor chip of FIG. 3;

FIGS. 5 to 8 are side cross-sectional views illustrating semiconductor chips according to various embodiments;

FIG. 9 is a flowchart illustrating a method of manufacturing the semiconductor chip of FIGS. 1 and 2 according to an example embodiment;

FIG. 10A is a perspective view illustrating a wafer having a device layer, FIG. 10B is an enlarged plan view of part A of FIG. 10A, and FIG. 10C is a side cross-sectional view taken along line III-III′ of FIG. 10B;

FIG. 11A is a perspective view illustrating a wafer having undergone laser grooving, FIG. 11B is an enlarged plan view of part A of FIG. 11A, and FIG. 11C is a cross-sectional side view taken along line III-III′ of FIG. 11B;

FIG. 12 is a cross-sectional side view illustrating an ashing process performed on a semiconductor substrate according to an example embodiment;

FIG. 13A is a perspective view illustrating a process of attaching a protective sheet to a semiconductor substrate according to an example embodiment, and FIG. 13B is a cross-sectional side view of a wafer with a protective sheet attached thereto, taken along line IV-IV′;

FIG. 14 is a cross-sectional side view illustrating a process of grinding a semiconductor substrate according to an example embodiment;

FIG. 15 is a cross-sectional side view illustrating a crack propagation state in a semiconductor substrate according to an example embodiment;

FIG. 16 is a cross-sectional side view illustrating a separation process of a semiconductor substrate according to an example embodiment;

FIG. 17 is a flow chart illustrating a method of manufacturing a semiconductor chip of FIG. 1 and FIG. 2 according to another embodiment;

FIGS. 18A to 18E are cross-sectional side views of a semiconductor wafer, illustrating a separation process of a semiconductor chip according to another embodiment according to the method illustrated in FIG. 17;

FIG. 19 is a cross-sectional side view illustrating a semiconductor package including a semiconductor chip according to an example embodiment; and

FIG. 20 is a cross-sectional side view illustrating a semiconductor package including a semiconductor chip according to another embodiment.

### DETAILED DESCRIPTION

Hereinafter, example embodiments will be described with reference to the attached drawings. Unless otherwise specifically stated, in this specification, terms such as “upper,” “top,” “upper surface,” “below,” “lower,” “side,” and the like are based on the drawings and may actually vary depending on the direction in which the components are disposed.

In addition, ordinal numbers such as “first,” “second,” “third,” etc. may be used as labels for specific elements, steps, directions, etc. to distinguish various elements, steps, directions, etc. Terms that are not described using “first,” “second,” etc. in the specification may still be referred to as “first” or “second” in the claims. In addition, terms that are referenced by a specific ordinal number (for example, “first” in a specific claim) may be described elsewhere with a different ordinal number (for example, “second” in the specification or another claim).

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

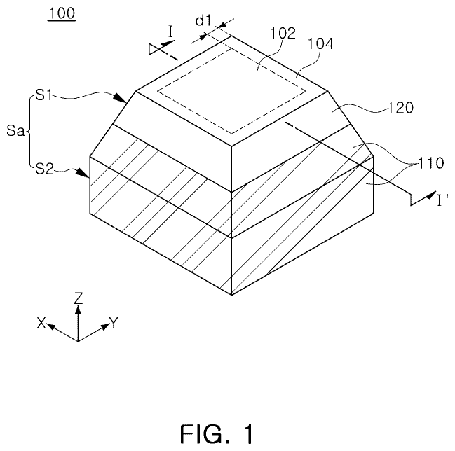

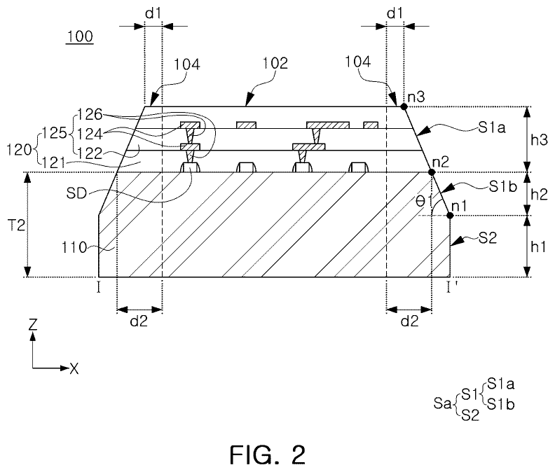

FIG. 1 is a perspective view illustrating a semiconductor chip according to various embodiments, and FIG. 2 is a cross-sectional side view of the semiconductor chip of FIG. 1 taken along line I-I′.

Referring to FIG. 1 and FIG. 2, a semiconductor chip 100 may include a semiconductor substrate 110 having an active surface (front or upper surface) and an inactive surface (back or lower surface) located opposite the active surface, and a device layer 120 disposed on the active surface of the semiconductor substrate 110.

The device layer 120 may include an integrated circuit area 102 and a cutting area 104 surrounding the integrated circuit area 102. The integrated circuit area 102 and the cutting area 104 may extend to the semiconductor substrate 110 in a direction (for example, in the Z-direction) perpendicular to the active surface.

The semiconductor substrate 110 may have a constant thickness T2 and may have various shapes depending on the chip shape, and for example, as illustrated in FIG. 1, may have quadrangular, e.g., rectangular or square, lower and upper surfaces, and the areas of the lower and upper surfaces may be different from each other.

The semiconductor substrate 110 may be a silicon substrate, but the present inventive concept is not limited thereto, and the semiconductor substrate 110 may include a semiconductor element such as germanium, or a compound semiconductor such as silicon carbide (SiC), gallium arsenide (GaAs), indium arsenide (InAs), and indium phosphide (InP). Alternatively, the semiconductor substrate 110 may have a silicon on insulator (SOI) structure. In some embodiments, the semiconductor substrate 110 may include a well doped with impurities, which is a conductive region, or another structure doped with impurities. In some embodiments, the semiconductor substrate 110 may have various device isolation structures such as a shallow trench isolation (STI) structure. If the thickness T2 of the semiconductor substrate 110 is too thin, the mechanical strength may be insufficient. According to one or more embodiments, the thickness T2 of the semiconductor substrate 110 may be about 30 μm to 50 μm.

A device layer 120 having an integrated circuit area 102 may be formed on the active surface of the semiconductor substrate 110. The integrated circuit area 102 may include a plurality of semiconductor devices SD. The semiconductor devices SD may include or may be memory devices and/or logic devices.

The memory devices may be volatile memory devices and/or nonvolatile memory devices. For example, the volatile memory devices may include or may be memory devices such as dynamic random access memory (DRAM), static RAM (SRAM), thyristor RAM (TRAM), zero capacitor RAM (ZRAM), and/or Twin Transistor RAM (TTRAM). The nonvolatile memory devices may include or may be memory devices such as, for example, flash memory, magnetic RAM (MRAM), spin-transfer torque MRAM (STT-MRAM), ferroelectric RAM (FRAM), phase change RAM (PRAM), resistive RAM (RRAM), nanotube RRAM, polymer RAM, nano floating gate memory, holographic memory, molecular electronics memory, and/or insulator resistance change memory.

The logic devices may be implemented as, for example, a microprocessor, a graphics processor, a signal processor, a network processor, an audio codec, a video codec, an application processor, or a system on chip, but is not limited thereto.

The integrated circuit area 102 may be surrounded by a cutting area 104.

The cutting area 104 may surround the integrated circuit area 102 in a frame shape (e.g., a rectangular ring shape or a square ring shape), but is not limited thereto. The cutting area 104 may have a constant width d1, e.g., in a horizontal direction (in an X-direction and/or in a Y-direction), on the upper surface of the device layer 120, but is not limited thereto, and the width in the X-direction and the width in the Y-direction may be different from each other in certain embodiments.

As described above, the integrated circuit area 102 is a region where semiconductor devices SD for memory and/or logic functions are formed, and the cutting area 104 is a region where such semiconductor devices are not formed. In some embodiments, a plurality of semiconductor dummy elements may be arranged in the cutting area 104.

In an example embodiment, the device layer 120 may be include an interlayer insulating film 121 disposed on the active surface and covering the semiconductor devices SD, and a wiring structure 125 disposed on the interlayer insulating film 121 and electrically connected to the semiconductor devices SD. The wiring structure 125 may have a multilayer (for example, two-layer) wiring structure in which low-K dielectric layers 122 and metal wiring (e.g., metal patterns/layers) 124 are alternately disposed/stacked. In addition, the wiring structure 125 may include a plurality of metal vias 126 disposed/extending in a direction (for example, Z-direction) perpendicular to the active surface of the semiconductor substrate 110. The metal wiring (e.g., metal patterns/layers) 124 and the metal vias 126 may be formed of a conductive material including at least one of, for example, aluminum (Al), copper (Cu), nickel (Ni), tungsten (W), platinum (Pt), and gold (Au). In the present embodiment, the metal wiring (e.g., metal patterns/layers) 124 is illustrated to have two layers, but is not limited thereto. Unlike the present embodiment, the metal wiring (e.g., metal patterns/layers) 124 may be formed of three layers or four or more layers.

The interlayer insulating film 121 and the low-κ dielectric layer 122 may be formed of a low-κ dielectric material. The low-κ dielectric material is a material having a lower dielectric constant than silicon oxide, and when used as the interlayer insulating film 121 for a semiconductor device SD, it may be advantageous in obtaining high integration and high speed of the semiconductor device SD due to improved insulation capability.

A dummy structure similar to the wiring structure 125 may be formed in the cutting area 104. For example, the dummy structure placed in the above-described cutting area 104 may include multilayer dummy wiring corresponding to the metal wiring (metal patterns/layers) 124 and/or the metal vias 126, together with an interlayer insulating film 121 and a low-κ dielectric layer 122. In some embodiments, a test pattern capable of testing a semiconductor device SD of an integrated circuit area 102 or a redistribution layer for connection between the test patterns may be included in the cutting area 104, or an align key for aligning a mask may be included. In addition, in some embodiments, a material film having various functions, such as a passivation film, may be additionally formed on the device layer 120.

A semiconductor chip 100 according to an example embodiment may have a semiconductor substrate 110 and a device layer 120 on the semiconductor substrate 110 have a continuous side. Referring to FIG. 1 and FIG. 2, the lower surface of the semiconductor substrate 110 may define/be the lower surface of the semiconductor chip 100, and the upper surface of the device layer 120 may define/be the upper surface of the semiconductor chip 100. The upper surface of the semiconductor substrate 110 and the lower surface of the device layer 120 may be in contact with each other and may have the same area. For example, each of side surfaces of the semiconductor chip 100 may have a smooth surface or a flat surface from an upper portion of the semiconductor substrate 110 to a lower portion of the device layer 120 which includes a boundary between the semiconductor substrate 110 and the device layer 120 without a bend between the lower surface of the device layer 120 and the upper surface of the semiconductor substrate 110, and may be formed continuously.

A side surface Sa including an inclined region may be disposed between the upper surface of the semiconductor chip 100 and the lower surface of the semiconductor chip 100.

The side surface Sa of the semiconductor chip 100 may include a first side surface S1 that is bent/angled from the upper surface of the semiconductor chip 100 and includes a region inclined at a first angle θ1 with respect to a plane parallel to the upper surface of the semiconductor chip 100, and a second side surface S2 that extends from the first side surface S1 and is disposed/connected to the lower surface of the semiconductor chip 100. For example, the upper surface of the semiconductor chip 100 extends in a horizontal direction, the first side surface S1 is an upper portion of the side surface Sa and extends from an edge of the upper surface of the semiconductor chip 100, and the second side surface S2 is a lower portion of the side surface Sa and extends from a bottom of the first side surface S1 to an edge of the lower surface of the semiconductor chip 100.

The first side surface S1 may include at least a portion of an inclined portion having a first angle θ1, and the second side surface S2 may be a vertical plane perpendicular to the lower surface of the semiconductor chip 100. The first angle θ1 may be defined as an angle of the first side surface S1 with respect to an imaginary horizontal line parallel to the lower surface of the semiconductor substrate 110 at an intersection n1 of the first side surface S1 and the second side surface S2, e.g., in a cross-sectional view. The intersection n1 in the present disclosure may be a node at which the first side surface S1 and the second side surface S2 meet, e.g., in a cross-sectional view. Accordingly, when the semiconductor chip 100 includes at least four side surfaces Sa, the first angles θ1 of the first side surfaces S1 at respective side surfaces Sa may be different from each other. The first angle θ1 may satisfy 50 degrees or more, and in certain embodiments, 60 degrees or more.

The first side surface S1 may be a slope formed by laser grooving when cutting into unit semiconductor chips, and may be formed by forming a laser groove having a slope at least in a portion between two facing unit semiconductor chips 100.

When the laser groove is formed to have a tip at the lower end (e.g., at the lowest point in a cross-sectional view), the angle formed by the inclined surfaces of the two unit semiconductor chips 100 at the tip, for example, the angle of the laser groove, forms an acute angle, e.g., up to maximum 80 degrees, and in certain embodiments, up to maximum 60 degrees.

Ashing may proceed from the inclined surfaces (side surfaces or sidewalls) of the laser groove to form the first side surface S1 of each semiconductor chip 100, and since the ashing proceeds isotropically, the first side surface S1 may maintain the first angle θ1 of the inclined surface by the laser groove. For example, the angle of the inclined surface may not be substantially changed by the ashing process, and may be in the above specified range when the ashing process is completed, but is not limited thereto.

The intersection n1 of the first side surface S1 and the second side surface S2 may be disposed on the side of the semiconductor substrate 110. For example, the second side surface S2 may extend from the lower surface of the semiconductor substrate 110 to a first height h1 at which the intersection/node n1 is positioned and may be bent at the first height h1 to be connected to the first side surface S1 such that the first side surface S1 begins from the first height h1 or from the intersection/node n1.

The first side surface S1 may include the upper portion S1b of the side surface of the semiconductor substrate 110 and may include the entire side surface Sla of the device layer 120 (e.g., from a bottom to a top of a side surface of the device layer 120). The first side surface S1 may extend by a second height h2 of the upper portion S1b of the side surface of the semiconductor substrate 110 and may extend to a third height h3 which is the entire height of the device layer 120.

The sum of the first height h1 and the second height h2 may correspond to (e.g., be the same as) the entire thickness T2 of the semiconductor substrate 110. The first side surface S1 and the second side surface S2 may have an inflection point as an intersection point n1 between the lower and upper sides of the semiconductor substrate 110. When viewed in the vertical cross-section of FIG. 2, the first side surface S1 of the semiconductor chip 100 may have an inclined straight line extending from the intersection/node point n1 to the upper end n3 of the semiconductor chip 100, but is not limited thereto, and may include a curve, for example, a curved surface, in some cases. The contact point n2 of the device layer 120 and the semiconductor substrate 110, e.g., in the cross-sectional view, may be positioned on an extension line between the upper end n3 of the semiconductor chip 100 and the intersection point n1, and the slope of the straight line may be maintained without having an inflection point between the device layer 120 and the contact point n2 of the semiconductor substrate 110. The slope of the straight line from the intersection point n1 to the contact point n2 within the semiconductor substrate 110 may be the same as the slope of the straight line from the contact point n2 to the upper end n3 of the device layer 120, but is not limited thereto.

This inclined side surface S1 may be disposed on the entire side surfaces of the semiconductor chip 100, and when the semiconductor chip 100 has quadrangular upper and lower surfaces, the area of the upper surface and the area of the lower surface of the semiconductor chip 100 are different from each other, and the area of the upper surface is smaller than the area of the lower surface. For example, the inclined first side surface S1 and the vertical second side surface S2 may be formed on all side surfaces of the semiconductor chip 100 as shown in FIG. 1. When viewed from the upper surface (e.g., in a plan view), the upper surface of the semiconductor chip 100 may be disposed within the area of the lower surface. For example, the whole area of the upper surface may overlap the lower surface in the Z-direction. As described above, the first angle θ1 of the inclined side surface S1 on the entire side surfaces Sa of the semiconductor chip 100 may be different from each other, but may satisfy 50 degrees or more, and in certain embodiments, 60 degrees or more.

Accordingly, horizontal cross-sectional areas of the semiconductor substrate 110 may be maintained the same from the level of the intersection/node n1 to the level of the lower surface. Horizontal cross-sectional areas of the semiconductor chip 100 increase in a direction moving from the upper surface to the intersection/node n1 and include an inclined first side surface S1, but the integrated circuit area 102 may include a uniform horizontal cross-sectional area from the upper surface to the lower surface of the device layer 120, and the frame-shaped cutting area 104 may be disposed to have a frame shape whose width gradually increases in a direction moving from the upper surface to the contact point n2. In this case, the semiconductor substrate 110 has horizontal cross-sectional areas that increase in a direction moving from the contact point n2 to the intersection/node n1, but may have a uniform horizontal cross-sectional area and a uniform width from the intersection n1 to the lower surface of the semiconductor chip 100. Therefore, the width d1 of the upper surface of the cutting area 104 of the device layer 120 may be smaller than the width d2 of the lower surface of the cutting area 104.

The first height h1 may be less than or equal to the second height h2, but is not limited thereto. The third height h3 may be greater than or equal to the first height h1, but is not limited thereto. The first height h1 may be less than the sum of the second height h2 and the third height h3.

The first side surface S1 of the side surface Sa of a semiconductor chip 100 may be cut through laser grooving when cutting a semiconductor structure in the wafer into respective unit semiconductor chips 100, and a groove having an incline may be formed so that the two side surfaces Sa facing each other within the cutting area 104 meet each other at the tip formed by laser grooving.

The unit semiconductor chip 100 cut along the groove includes a first side surface S1 including an incline along the groove as illustrated in FIGS. 1 and 2, and may include a second side surface S2 of the semiconductor substrate 110 cut vertically below the groove.

A semiconductor chip 100 of the present embodiment may improve strength and reliability on the side surface Sa of the semiconductor chip 100 by reducing or eliminating the heat affected zone HAZ caused by laser grooving through an ashing process after the laser grooving.

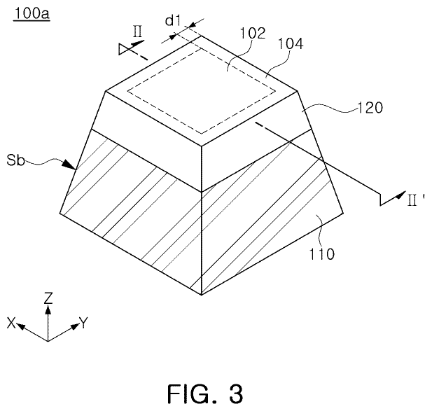

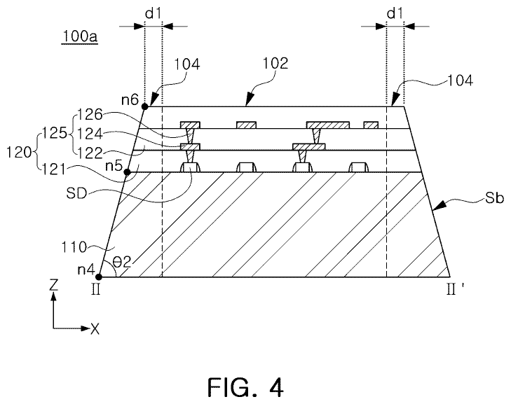

Hereinafter, a semiconductor chip according to another embodiment will be described with reference to FIGS. 3 and 4.

FIG. 3 is a perspective view illustrating a semiconductor chip according to various embodiments, and FIG. 4 is a cross-sectional side view of the semiconductor chip of FIG. 3 cut along line II-II′.

A semiconductor chip 100a of FIGS. 3 and 4 is the same as the semiconductor chip 100 of FIGS. 1 and 2 except for the shape of the side surface Sb.

In the semiconductor chip 100a according to the example embodiment, the lower surface of the semiconductor substrate 110 defines/is the lower surface of the semiconductor chip 100a, and the upper surface of the device layer 120 may define/be the upper surface of the semiconductor chip 100a. The upper surface of the semiconductor substrate 110 and the lower surface of the device layer 120 may be in contact with each other and have the same area. For example, a fold may not be formed between the lower surface of the device layer 120 and the upper surface of the semiconductor substrate 110.

A side surface Sb including an inclined region may be disposed between the upper surface of the semiconductor chip 100a and the lower surface of the semiconductor chip 100a. For example, the side surface Sb of the semiconductor chip 100a may include an inclined surface that is inclined at a second angle θ2, e.g., with respect to the lower surface of the semiconductor chip 110a. For example, the inclined surface may extend from the upper surface of the semiconductor chip 100a to the lower surface of the semiconductor chip 100a without a fold/bend in the inclined surface. However, when the semiconductor chip 100a includes at least three side surfaces Sb, e.g., four side surfaces Sb, the second angles θ2 of each side surface Sb may be different from other side surfaces Sb of the semiconductor chip 100a.

When viewed in the vertical cross-section of FIG. 4, a portion of the side surface Sb forming a side surface of the device layer 120 extending from the upper end no of the semiconductor chip 100a to the contact point n5 of the device layer 120 and the semiconductor substrate 110 may have an inclined straight line and may not include a curve that represents a curved surface. In the cross-sectional view of FIG. 4, a portion of the side surface Sb forming a side surface of the semiconductor substrate 110 extending from the lower end n4 of the semiconductor chip 100a to the contact point n5 may have an inclined straight line and may not include a curve that represents a curved surface. In this case, the slope of the portion of the side surface Sb forming the side surface of the device layer 120 is the same as the slope of the portion of the side surface Sb forming the side surface of the semiconductor substrate 110, and the two portions of the side surface Sb may be continuously extended.

Such continuous slopes may be equally disposed on the entire side surfaces Sb of the semiconductor chip 100a, and when the semiconductor chip 100a has quadrangular upper and lower surfaces, the area of the upper surface and the area of the lower surface of the semiconductor chip 100a are different from each other, and the area of the upper surface is smaller than the area of the lower surface. When viewed from the upper surface (e.g., in a plan view), the upper surface of the semiconductor chip 100a may be disposed within the area of the lower surface. For example, the whole area of the upper surface may overlap the lower surface in the Z-direction.

Therefore, horizontal cross-sectional areas may increase from the upper surface to the lower surface of the semiconductor chip 100a, and the frame-shaped cutting area 104 may be disposed to have a frame shape of whose sides have a width d1 gradually increases from the upper surface to the lower surface of the cutting area 104. On the other hand, even if the side surface Sb of the semiconductor chip 100a includes an inclined surface, horizontal cross-sectional areas of the integrated circuit area 102 may be the same from the upper surface to the lower surface of the device layer 120.

The inclined side surface Sb of the semiconductor chip 100a may be formed through laser grooving when cutting a semiconductor structure in the wafer into individual unit semiconductor chips 100a, and a groove having an incline may be formed so that two facing sides meet at a tip within or vertically overlapping the cutting area 104.

The unit semiconductor chip 100a cut along the groove may include an inclined side surface Sb along a sidewall of the groove as illustrated in FIGS. 1 and 2.

This semiconductor chip 100a may improve the strength and reliability on the side surface Sb of the semiconductor chip 100a by reducing or removing the heat affected zone due to laser grooving through an ashing process after the laser grooving.

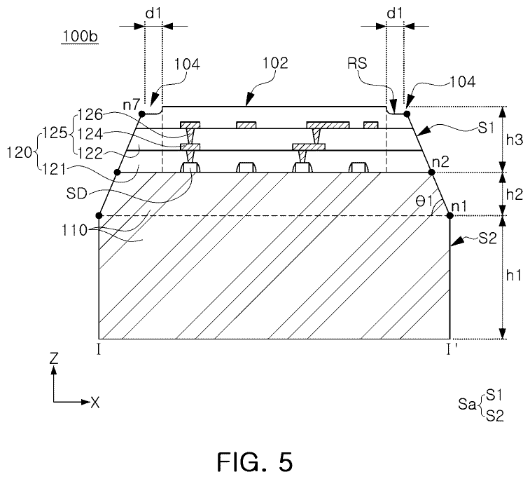

Hereinafter, a semiconductor chip 100b according to another embodiment will be described with reference to FIGS. 5 to 8.

Referring to FIG. 5, the semiconductor chip 100b is the same as the semiconductor chip 100 of FIG. 2 except for the shape of the cutting area 104.

The semiconductor chip 100b according to the example embodiment may include a recessed portion RS on the upper surface of the cutting area 104. For example, the recessed portion RS may extend along an edge of an upper surface of the semiconductor chip 100b to surround the integrated circuit area 102 so that the level n7 of the upper surface of the cutting area 104 is lower than the level of the upper surface of the integrated circuit area 102. The recessed portion RS may form a stepped structure connecting the side surface Sb and the upper surface of the semiconductor chip 100b by being interposed therebetween.

The recessed portion RS may be disposed on the entire upper surface of the cutting area 104, and may have a curved surface toward the bottom (e.g., a concave surface), but is not limited thereto. In certain embodiments, the recessed portion RS may be disposed only on a part of the cutting area 104, and the cutting area 104 may have an upper surface at the same level as the upper surface of the integrated circuit area 102 adjacent to the edge of the integrated circuit area 102, and the recessed portion RS may have a lower surface at a lower level n7 than the upper surface of the cutting area 104 while forming a step from the upper surface of the cutting area 104.

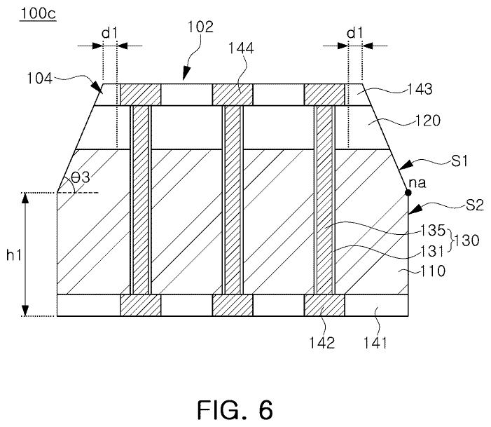

Referring to FIG. 6, a semiconductor chip 100c may include through-electrodes 130, upper pads 144 on the device layer 120, and lower pads 142 on a lower surface of the semiconductor substrate 110.

Each of the through-electrodes 130 may have a pillar structure penetrating the semiconductor substrate 110. The through-electrode 130 may continuously penetrate the device layer 120, or alternatively, may penetrate the semiconductor substrate 110 and be connected to and contact the wiring layers of the device layer 120.

The bottom of the through-electrode 130 may be connected to and contact the lower pads 142, and the top of the through-electrode 130 may be connected to and contact the upper pads 144. In this manner, the through-electrode 130 may electrically connect the lower pads 142 and the upper pads 144. The through-electrode 130 may include a via plug 135 and an insulating liner 131 surrounding the via plug 135. The insulating liner 131 may electrically isolate the via plug 135 from the semiconductor substrate 110.

The semiconductor chip 100c may have an upper insulating layer 143 disposed on the upper surface of the device layer 120, and a lower insulating layer 141 disposed on the lower surface of the semiconductor substrate 110 as a lower passivation layer.

The semiconductor chip 100c including the through-electrodes 130 may also include an upper surface and a lower surface, and may have side surfaces S1, S2 disposed to connect the upper surface and the lower surface.

The upper surface of the semiconductor chip 100c may be defined as the upper surface of the upper insulating layer 143, and the lower surface of the semiconductor chip 100c may be defined as the lower surface of the lower insulating layer 141.

Regarding the upper surface and lower surface of the semiconductor chip 100c, the upper surface has a smaller area than the lower surface, and the side surfaces S1, S2 therebetween may include inclined surfaces. The side surfaces S1, S2 of the semiconductor chip 100c may include a first side surface S1 that is inclined at a third angle θ3 with respect to an imaginary plane parallel to the upper surface or lower surface of the semiconductor chip 100c, and a second side surface S2 that extends from a bottom of the first side surface S1 to an edge of the lower surface of the semiconductor chip 100c.

The first side surface S1 may be an inclined flat surface having a third angle θ3, and the second side surface S2 may be a vertical flat surface perpendicular to the lower surface of the semiconductor chip 100c and extending in the Z-direction.

On the vertical cross section of FIG. 6, the bending points na between the first side surface S1 and the second side surface S2 may be disposed on the side surface of the semiconductor substrate 110. For example, the second side surface S2 extends from the lower surface of the lower insulating layer 141 to the first height h1 in a vertical direction and may be connected to the first side surface S1 at the first height h1 such that the side surface of the semiconductor chip 100c bends at the first height h1 in that the first side surface S1 is an inclined flat surface.

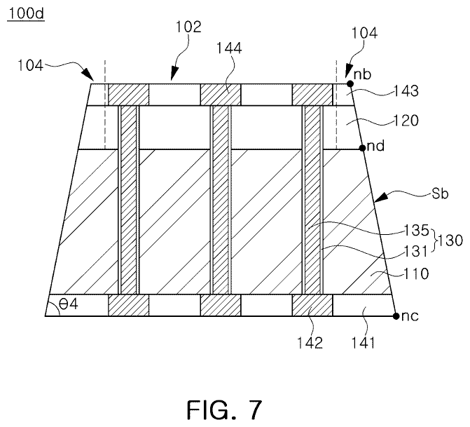

Referring to FIG. 7, a semiconductor chip 100d may be identical to the semiconductor chip 100a of FIG. 4, except that it includes through-electrodes 130, upper pads 144 on the device layer 120, and lower pads 142 on a lower surface of the semiconductor substrate 110.

The semiconductor chip 100d may include through-electrodes 130, upper pads 144 on the device layer 120, and lower pads 142 on the lower surface of the semiconductor substrate 110.

Each of the through-electrodes 130 may have a pillar structure penetrating the semiconductor substrate 110. The through-electrode 130 may continuously penetrate the device layer 120, or alternatively, may penetrate the semiconductor substrate 110 and be connected to and contact the wiring layers of the device layer 120.

The bottom of the through-electrode 130 may be connected to and contact the lower pads 142, and the top of the through-electrode 130 may be connected to and contact the upper pads 144. In this manner, the through-electrode 130 may electrically connect the lower pads 142 and the upper pads 144. The through-electrode 130 may include a via plug 135 and an insulating liner 131 surrounding the via plug 135. The insulating liner 131 may electrically isolate the via plug 135 from the semiconductor substrate 110.

The semiconductor chip 100d may have an upper insulating layer 143 placed on the upper portion/surface of the device layer 120, and a lower insulating layer 141 placed below the semiconductor substrate 110 as a lower passivation layer.

In a cross-sectional view as shown in FIG. 7, the side surface of the device layer 120 extending from the upper end nb of the semiconductor chip 100d to the contact point nd of the device layer 120 and the semiconductor substrate 110 may have an inclined straight line and may not include a curved line that represents a curved surface. For example, the side surface of the semiconductor substrate 110 extending from the lower end nc (lower end of the lower insulating layer 141) of the semiconductor chip 100d to the contact point nd may have an inclined straight line. In this case, the slope (having an angle θ4 with respect to the lower surface of the semiconductor chip 100d) extending from the upper end nb of the semiconductor chip 100d (upper end of the upper insulating layer 143) to the contact point nd is the same as the slope (having an angle θ4 with respect to the lower surface of the semiconductor chip 100d) of the side surface of the semiconductor substrate 110, and the two side surfaces may continuously extend to form a side surface Sb of the semiconductor chip 100d.

The continuous slope as described above may be equally disposed on the entire side surfaces Sa of the semiconductor chip 100d, and when the semiconductor chip 100d has quadrangular upper and lower surfaces, the area of the upper surface and the area of the lower surface of the semiconductor chip 100d are different from each other, and the area of the upper surface is smaller than the area of the lower surface, and when viewed from the upper surface (e.g., in a plan view), the upper surface of the semiconductor chip 100d may be disposed within the area of the lower surface. For example, the whole area of the upper surface may overlap the lower surface in the Z-direction.

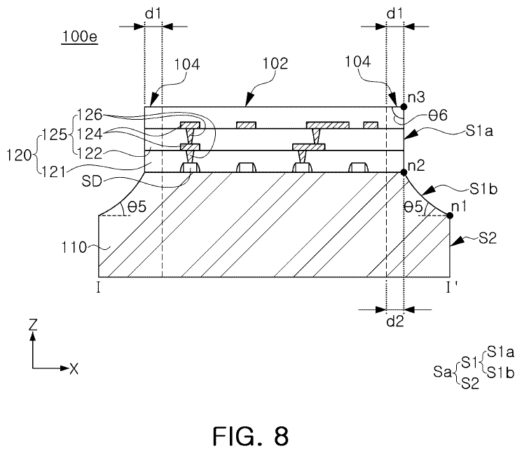

Referring to FIG. 8, a semiconductor chip 100e is the same as the semiconductor chip 100 of FIG. 2 except for the shape of the first side surface S1.

In a semiconductor chip 100e according to an example embodiment, a first side surface S1 of the semiconductor chip 100e extending from the upper end n3 of the semiconductor chip 100e to the intersection/node point n1 may have at least partially a curved surface. The first side surface S1 may include an upper side surface Sla bent at a sixth angle θ6 from the upper surface of the semiconductor chip 100e and a lower side surface S1b having a curved surface extending from a lower end of the upper side surface Sla to the intersection/node point n1.

The upper side surface Sla and the lower side surface S1b may correspond to the side surface Sla of the device layer 120 and the upper portion S1b of the side surface of the semiconductor substrate 110, respectively, but are not limited thereto, and the upper side surface Sla may extend further downwards passing the upper surface of the semiconductor substrate 110 by a predetermined depth.

The sixth angle θ6 of the upper side surface Sla is an angle bent from the upper surface of the semiconductor chip 100e (e.g., an angle between the upper surface of the semiconductor chip 100e and the upper side surface Sla in a cross-sectional view as shown in FIG. 8), and may satisfy 90 degrees to 120 degrees. The lower side surface S1b extends from a bottom end of the upper side surface Sla to the intersection/node point n1 and has a curved surface at least in a part, and a fifth angle θ5 formed between the lower side surface S1b and an imaginary plane parallel to the upper surface of the semiconductor chip 100e at the intersection point n1 as shown in FIG. 8 may satisfy 50 degrees or more, and in certain embodiments, 60 degrees or more. Accordingly, the upper part of the first side surface S1 may extend vertically and gradually inclines in a direction moving downward, and also by this shape, horizontal cross-sectional areas of the semiconductor chip 100e may increase in a direction moving downward from the upper surface of the semiconductor substrate 110 to the intersection/node point n1 as shown in FIG. 8.

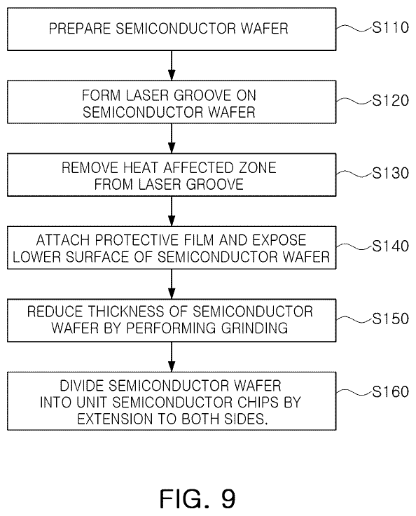

Hereinafter, a method of manufacturing a semiconductor chip will be described with reference to FIGS. 9 to 16.

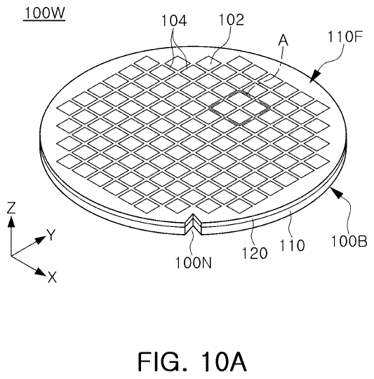

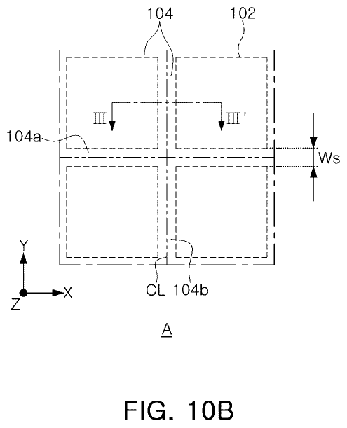

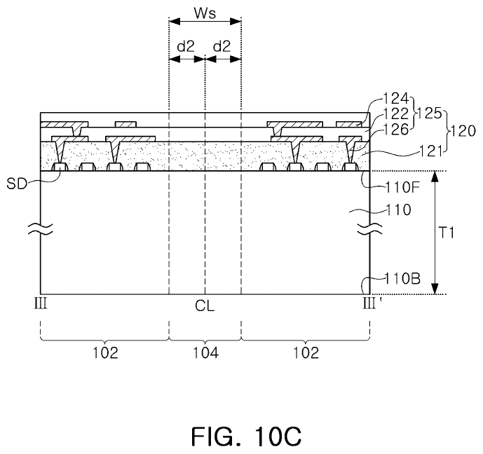

FIG. 9 is a flowchart illustrating a method of manufacturing a semiconductor chip according to an example embodiment, FIG. 10A is a perspective view illustrating a wafer having a device layer, FIG. 10B is an enlarged plan view of part A of FIG. 10A, and FIG. 10C is a cross-sectional view taken along line III-III′ of FIG. 10B.

First, a semiconductor wafer 100W of FIGS. 10A to 10C is prepared (S110).

The wafer 100W according to an example embodiment includes a semiconductor substrate 110 having an active surface 110F and an inactive surface 110B located opposite the active surface 110F, and a device layer 120 disposed on the active surface 110F of the semiconductor substrate 110.

The above wafer 100W may have a notch 100N used as a reference point for wafer alignment in an edge of the wafer. The device layer 120 may include integrated circuit areas 102 and a cutting area 104. The semiconductor substrate 110 may be a circular wafer having a constant first thickness T1. For example, the semiconductor substrate 110 may be a silicon wafer. However, the present inventive concept is not limited thereto, and the semiconductor substrate 110 may be a substrate formed of a semiconductor element such as germanium, or a compound semiconductor wafer such as silicon carbide (SiC), gallium arsenide (GaAs), indium arsenide (InAs), and indium phosphide (InP). Alternatively, the semiconductor substrate 110 may have a silicon on insulator (SOI) structure. In some embodiments, the semiconductor substrate 110 may include an impurity-doped well or an impurity-doped structure, which is a conductive region. In addition, the semiconductor substrate 110 may have various device isolation structures, such as a shallow trench isolation (STI) structure.

If the first thickness T1 of the semiconductor substrate 110 is too thin, the mechanical strength may be insufficient, and if the first thickness T1 is too thick, the time required for subsequent grinding may be long, which may reduce the productivity of the semiconductor chip 100. For example, the first thickness T1 of the semiconductor substrate 110 may be in the range of about 0.1 mm to 1 mm.

The integrated circuit areas 102 may be disposed to be isolated from each other by a cutting area 104. The cutting area 104 may be referred to as a scribe lane. The above-mentioned cutting area 104 may include a first portion 104a extending in a row direction (for example, X-direction) and a second portion 104b extending in a column direction (for example, Y-direction), of which the first portion 104a and the second portion 104b intersect each other. The above-mentioned first portion 140a and the second portion 104b of the cutting area 104 may each be in the form of a straight lane having a constant width Ws. As illustrated in FIG. 10a, the integrated circuit areas 102 may be arranged in multiple rows and multiple columns with the cutting area 104 interposed therebetween. Each of the integrated circuit areas 102 may be surrounded by the cutting area 104 and spaced apart from the other integrated circuit areas 102.

As described above, the plurality of integrated circuit areas 102 are regions where semiconductor devices SD for memory or logic functions are formed, and the cutting area 104 is a region where such semiconductor devices are not formed. In some embodiments, a plurality of semiconductor dummy elements may be arranged in the cutting area 104.

In this embodiment, the device layer 120 may include an interlayer insulating film 121 disposed on the active surface 100F and covering the semiconductor devices SD, and a wiring structure 125 disposed on the interlayer insulating film 121 and electrically connected to the semiconductor devices SD. The wiring structure 125 may have a multilayer (for example, two-layer) wiring structure in which low-κ dielectric layers 122 and metal wiring (e.g., metal patterns/layers) 124 are alternately disposed/stacked. In addition, each layer of the wiring structure 125 may include a plurality of metal vias 126 disposed/extending in a direction (for example, Z-direction) perpendicular to the active surface 110F of the semiconductor substrate 110. For example, the metal wiring (metal patterns/layers) 124 and the metal vias 126 may be formed of a conductive material including at least one of aluminum (Al), copper (Cu), nickel (Ni), tungsten (W), platinum (Pt), and gold (Au).

The interlayer insulating film 121 and the low-κ dielectric layers 122 may be formed of a low-κ dielectric material. The low-κ dielectric material is a material having a lower dielectric constant than silicon oxide, and when used as the interlayer insulating film 121 for a semiconductor device SD, it may be advantageous in obtaining high integration and high speed of the semiconductor device SD due to improved insulation capability.

A dummy structure similar to the wiring structure 125 may be formed in the cutting area 104. For example, the dummy structure placed in the cutting area 104 may include multilayer dummy wiring corresponding to the metal wiring (metal patterns/layers) 124 and/or the metal vias 126, together with an interlayer insulating film 121 and a low-κ dielectric layer 122. In some embodiments, a test pattern capable of testing a semiconductor device SD in the integrated circuit areas 102 or a redistribution layer for connection between the test patterns may be included in the cutting area 104, or an align key for aligning a mask may be included in the cutting area 104.

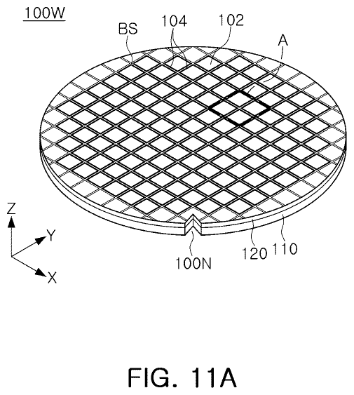

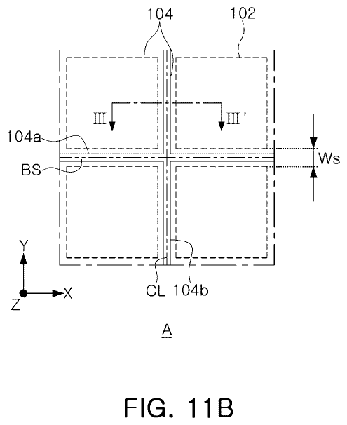

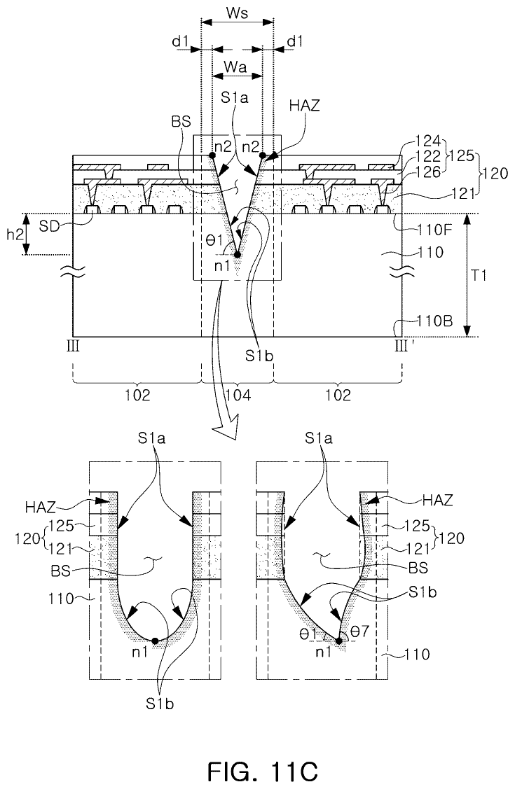

Referring to FIG. 9 and FIG. 11A to FIG. 11C, a laser groove may be formed on the semiconductor wafer 100W (S120).

FIG. 11A is a perspective view illustrating a wafer on which laser grooving has been performed, FIG. 11B is an enlarged plan view of part A of FIG. 11A, and FIG. 11C is a cross-sectional view taken along line III-III′ of FIG. 11B.

As illustrated in FIG. 11A, a cutting line CL is placed in the center of the cutting area 104, and a groove BS may be formed from the upper surface of the device layer 120 to a predetermined depth along the cutting area 104. For example, the upper surface of the device layer 120 may be an upper surface (or a front surface) of the semiconductor wafer 100W. When an upper insulating layer 143 is formed on the upper surface of the device layer 130 as shown in FIGS. 6 and 7, the upper surface of the upper insulating layer 143 may be an upper surface (or front surface) of the semiconductor wafer 100W. In this embodiment, each of the plurality of integrated circuit areas 102 has a quadrangular shape (rectangular or square shape), and when arranged in a plurality of rows and a plurality of columns with the cutting area 104 therebetween, the grooves BS are formed in row directions and column directions along the cutting area 104, and the grooves BS of the row directions and column directions may intersect each other near corners of adjacent four integrated circuit areas 102 located in two adjacent rows and two adjacent columns of the integrated circuit areas 102.

A laser having a wavelength that penetrates the semiconductor substrate 110 may be provided by dispersing energy so as to form a groove BS along the cutting line CL of the semiconductor substrate 110. In this manner, by radiating the laser along the cutting line CL, laser grooving may be performed so that two side surfaces of the groove have upper ends with a predetermined distance/width Wa and lower ends of the two side surfaces touching each other at one point, e.g., in a cross-sectional view, within the width Ws of the cutting area 104.

The laser radiation device may radiate the laser while supporting the semiconductor substrate 110 by suction with vacuum pressure on a chuck table and moving the semiconductor substrate/wafer 110/100W in the row direction (for example, X-direction) and the column direction (for example, Y-direction).

The laser emitted from the laser radiation device may intensively irradiate the semiconductor substrate 110 so that the temperature of the semiconductor substrate 110 may be increased to about 600° C. For example, the semiconductor substrate 110 may be partially melted by the laser focused on the semiconductor substrate 110 and become a heat affected zone HAZ.

The heat affected zone HAZ may be formed along the inclined first side surface S1 of the groove BS of the semiconductor substrate 110 to a predetermined thickness.

When a dicing process is performed to separate the semiconductor wafer 100W into semiconductor chips 100 each including an integrated circuit area 102, a groove BS may be formed along the cutting area 104 through the laser grooving process. For example, in the cutting area 104 between the two integrated circuit areas 102, the groove BS is formed such that the width thereof becomes narrower in a direction receding from the upper surface downwards, and the two side surfaces may touch each other to form a line consisting of common points at the lower ends of the two side surfaces along the cutting line CL to form a tip on the vertical cross section.

The width Wa of the groove BS on the upper surface of the device layer 120 may be equal to or smaller than the width Ws of the cutting area 104, and half of the difference between the width Wa of the groove BS and the width Ws of the cutting area 104 may be defined as the upper surface width d1 of the cutting area 104 of FIG. 2.

The groove BS in the cutting area 104 formed through laser grooving extends to the bending point n1, and a tip is formed at the bottom of the groove BS so that a V-shaped groove BS, e.g., in a cross-sectional view, has a bottom end at the bending point n1, so that the laser energy may be concentrated. The bending point n1 may be disposed at a depth from the upper surface of the semiconductor substrate 110 equal to the second height h2, and may be disposed at a level higher than ½ of the first thickness T1 from the lower surface of the semiconductor substrate 110.

When the groove BS formed through the laser grooving process has a V shape, the width between the inclined surfaces S1 of the groove BS becomes smaller in a direction receding from the upper surface of the device layer 120, and may include a tip at the intersection/node point n1 without a bottom surface, for example, an intersection that appears as the tip at the intersection/node point n1. Therefore, the area exposed to the laser may be significantly reduced because there is no bottom surface. As illustrated in the enlarged view of FIG. 11C (bottom left), the shape of the laser groove BS may have a bell shape when viewed in a vertical cross-section. For example, the upper region of the laser groove BS may be bent vertically from the upper surface (e.g., extend in a vertical direction), and opposite sidewalls of the groove may be formed to have curved surfaces to meet each other at the tip such that the groove forms a bell shape in a cross-sectional view as shown in FIG. 11C.

Alternatively, as in another enlarged view of FIG. 11C (bottom right), the inclination angles θ1 and θ7 of the two opposite sidewalls of the laser groove BS may be different from each other. For example, the inclination angle θ1 of one sidewall at the tip may be smaller than the inclination angle θ7 of the other sidewall at the tip. In this case, the inclination angles θ1 and θ7 of the two sidewalls may satisfy 50 degrees or more, and in certain embodiments, 60 degrees or more. The laser groove BS may be modified in various ways except that the two sidewalls contact each other at the tip. Therefore, the angle between surfaces of the two opposite sidewalls at the tip of the laser groove BS, for example, the angle of the laser groove BS in a cross-sectional view, is an acute angle, e.g., up to 80 degrees, and in certain embodiments, up to 60 degrees.

When the groove BS is formed through a laser grooving process, the strength of the semiconductor chip 100 may be reduced by 15% or more in the heat affected zone HAZ, which is a damaged area due to laser heat, and a vertical crack may occur through an interface with another material having a low adhesive strength between them, which may cause a problem of reduced reliability.

In the example embodiment, by forming the groove BS through the laser grooving process to have a tip, the heat affected zone HAZ may be significantly reduced because there is no lower surface. For example, there is not a flat bottom surface in the groove BS, which is beneficial to reducing the heat affected zone HAZ.

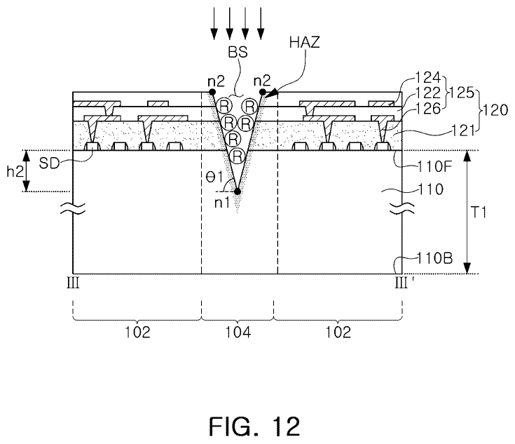

FIG. 12 is a cross-sectional view illustrating a process of performing an ashing process on a semiconductor substrate according to an example embodiment.

Referring to FIG. 9 and FIG. 12, an ashing process may be performed on the semiconductor wafer 100W on which laser grooving has been performed (S130).

For example, a reaction gas such as oxygen (O₂), hydrogen (H₂), water vapor (H₂O), nitrogen (N₂), fluorine-based gas such as CF4 and SF6 is formed in a plasma state and provided on the surface of the grooves BS, and the heat affected zone HAZ formed on the inclined surface S1 of the grooves BS may be removed by reacting the active radical (R) in the plasma with the heat affected zone HAZ on the semiconductor substrate 110.

By performing the plasma ashing process in this manner, the heat affected zone HAZ on the surface of the grooves BS may be significantly reduced. Plasma ashing is performed isotropically so that the slope of the laser groove BS after ashing may maintain the first angle θ1, but the ashing process is not limited thereto. Wet ashing/etching may also be performed to selectively remove only the heat affected zone HAZ of the slope of the grooves RS using an etchant (or an ashing agent). Such an ashing/etching process may be performed so that the laser grooves BS may be formed to maintain a V-shape without the heat affected zone HAZ.

FIG. 13A is a perspective view illustrating a process of attaching a protective sheet to a semiconductor substrate (e.g., a wafer) according to an example embodiment, and FIG. 13b is a cross-sectional side view of a wafer with a protective sheet attached taken along line IV-IV′ of FIG. 3A.

Referring to FIG. 9 and FIG. 13A and FIG. 13B, a protective sheet 200 is attached on the device layer 120 of the wafer 100W (S140).

The wafer 100W may be positioned so that the surface to which the protective sheet 200 is attached faces a support such as a chuck table during a subsequent cutting process. The protective sheet 200 may protect the integrated circuit areas 102 while the cutting process of the wafer 100W is performed. For example, the protective sheet 200 may be a polyvinylchloride (PVC)-based polymer sheet, and may be attached onto the device layer 120 by an acrylic resin-based adhesive, and the acrylic resin-based adhesive may be applied to the device layer 120 and/or the protective sheet 200 with a thickness of about 2 μm to about 10 μm. The protective sheet 200 may have a thickness of about 60 μm to about 200 μm. In some embodiments, the protective sheet 200 may be a die attach film DAF. The protective sheet 200 may have a circular shape having a diameter substantially the same as that of the wafer 100W.

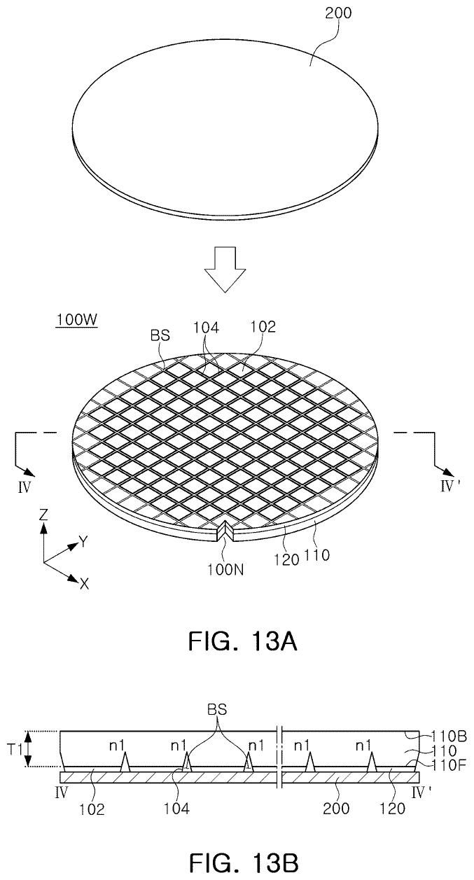

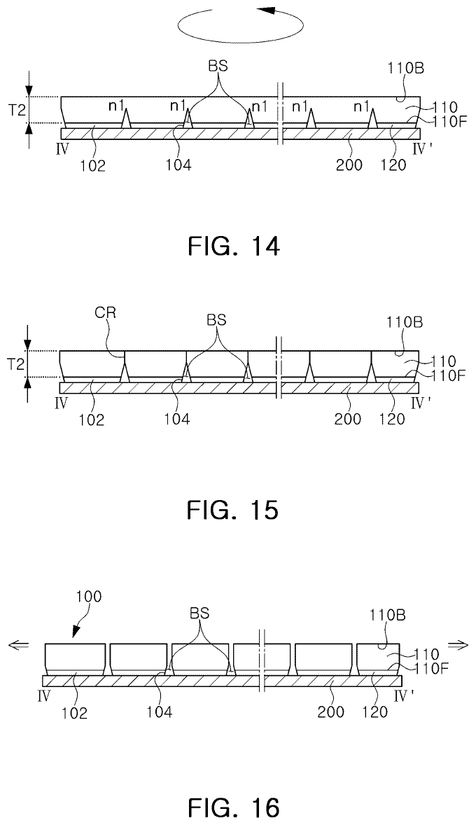

FIG. 14 is a cross-sectional view illustrating a process for polishing a semiconductor substrate according to an example embodiment.

Referring to FIG. 9 and FIG. 14, a back-grinding process for processing a lower surface of a semiconductor substrate 110 of the semiconductor wafer 100W may be performed (S150). For example, the lower surface of the semiconductor substrate 110 may be a lower surface (or a back surface) of the semiconductor wafer 100W. When a lower insulating layer 141 is formed on the lower surface of the semiconductor substrate 110, a lower surface of the lower insulating layer 141 may be a lower surface (or a back surface) of the semiconductor wafer 100W.

By the back-grinding process, the first thickness T1 of the semiconductor substrate 110 may be reduced to satisfy the second thickness T2 of FIG. 2.

At this time, even at the second thickness T2, grinding may be performed so that a distance corresponding to the first height h1 may be maintained from the grinding surface to the tip formed at the intersection/node point n1 so that the groove BS formed by laser grooving is not exposed to the lower surface. At this time, the first height h1 may satisfy 10 to 15 μm, but is not limited thereto.

In addition, a crack may be generated as shown in FIG. 14 by the back grinding process.

FIG. 15 is a cross-sectional view illustrating crack propagation in a semiconductor substrate 110 according to an example embodiment.

When the semiconductor substrate 110 is reduced to the second thickness T2 by polishing the inactive surface 110B of the semiconductor substrate 110 using a polishing device, a crack CR may propagate from the groove BS. The polishing device may include a chuck table that supports the semiconductor wafer 100W including the semiconductor substrate 110 and a grinder that polishes the semiconductor substrate 110. The grinder may move while rotating, and a polishing pad may be attached to the lower portion of the grinder. When the semiconductor substrate 110 is polished with a polishing device to have a desired second thickness T2, a crack CR may start from the groove BS in the cutting area 104 and propagate to the inactive surface 110B of the polished semiconductor substrate 110.

For example, when the polishing process is performed while physical pressure is applied to the semiconductor substrate 110, the polished semiconductor substrate 110 may be brittlely fractured. Brittle fracture refers to a case where an object is broken without permanent deformation when force of elastic limit or more is applied. Therefore, while polishing the inactive surface 110B of the semiconductor substrate 110, the semiconductor substrate 110 that is gradually becoming thinner may be brittlely fractured by the crack CR propagated from the groove BS. As the propagated crack CR is formed along the cutting area 104 that isolates the integrated circuit areas 102, the integrated circuit areas 102 may be separated into individual semiconductor chips 100 by brittle fracture of the semiconductor substrate 110.

FIG. 16 is a cross-sectional view illustrating a process for separating a semiconductor substrate according to an example embodiment.

Referring to FIG. 9 and FIG. 16, the protective sheet 200 may be expanded so that individual semiconductor chips 100 are separated from the semiconductor wafer 100W (S160). By this expansion, each semiconductor chip 100 may be separated into a unit by a crack CR extending from the groove BS to the lower surface of the semiconductor substrate 110. At this time, the protective sheet 200 may be further expanded such that the semiconductor chips 100 forming respective units move away from each other as illustrated in FIG. 16. At this time, as an example, the protective sheet 200 may be placed on a jig and the jig may be pushed up to expand the protective sheet 200. Accordingly, the semiconductor wafer 100W may be divided into individual semiconductor chips 100 by expanding gaps formed along the groove BS. At this time, the protective sheet 200 may be divided together with the semiconductor wafer 100W and may remain on the individual semiconductor chips 100, or may remain in an extended state.

In this manner, after the laser groove BS is formed in a V shape, the heat affected zone HAZ is removed by the ashing process, and then the protective sheet 200 is expanded to separate the semiconductor wafer 100W into the unit semiconductor chips 100, thereby providing semiconductor chips 100 with a significantly-reduced heat affected zone HAZ on the sides.

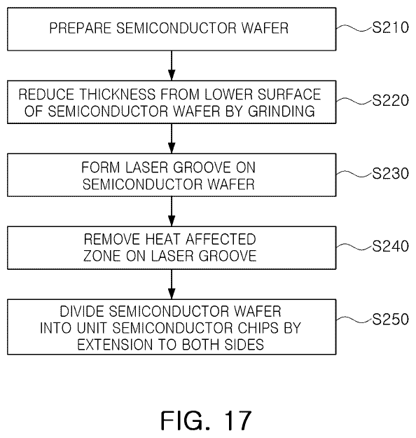

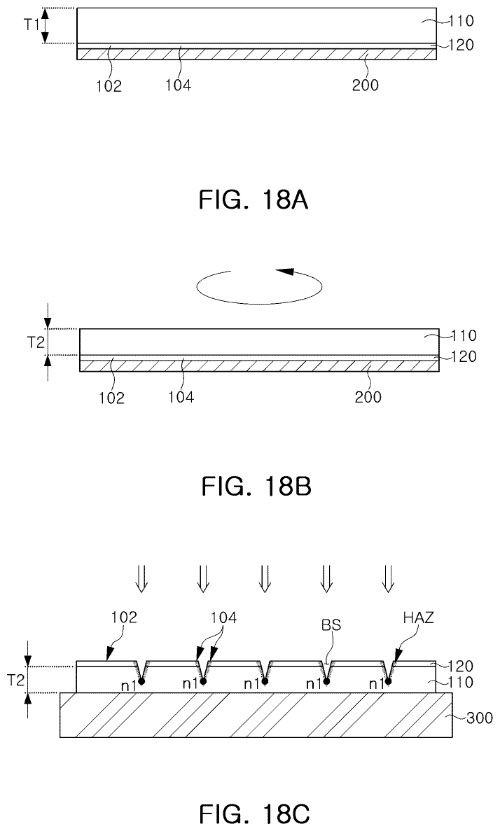

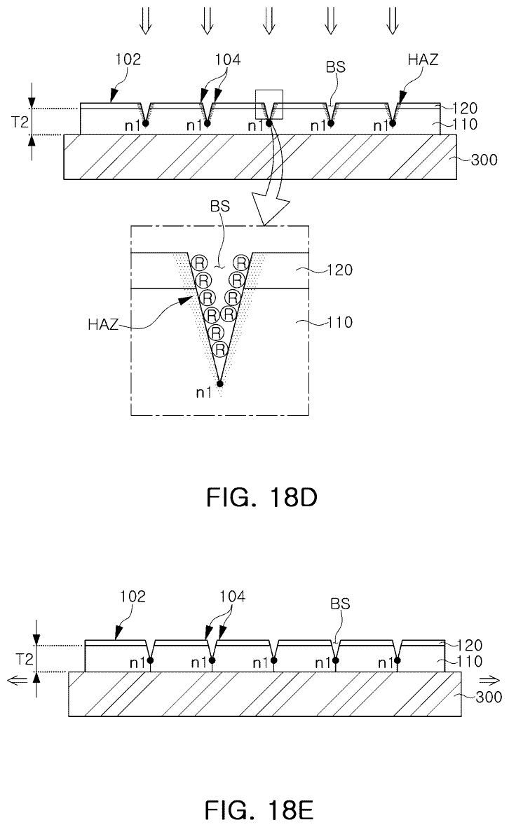

Hereinafter, a method of manufacturing a semiconductor chip according to another embodiment will be described with reference to FIGS. 17 and 18A to 18E.

FIG. 17 is a flowchart illustrating a method of manufacturing a semiconductor chip according to another embodiment.

Referring to FIGS. 17 and 18A, a semiconductor wafer 100W is prepared (S210).

A protective sheet 200 is attached to the upper surface of the device layer 120 of the semiconductor wafer 100W, and the lower surface of the semiconductor wafer 100W may be exposed. At this time, the thickness of the semiconductor wafer 100W may satisfy the first thickness T1 that is greater than the second thickness T2 of the semiconductor substrate 110 of FIG. 2.

Referring to FIG. 17 and FIG. 18B, a back-grinding process for processing the lower surface of the semiconductor substrate 110 of the semiconductor wafer 100W may be performed (S220).

By the back-grinding process, the first thickness T1 of the semiconductor substrate 110 may be reduced to satisfy the second thickness T2 of FIG. 2.

At this time, grinding may be performed so that a distance corresponding to the first height h1 is obtained from the grinding surface to the tip formed at the intersection/node point n1 so that the groove BS formed by the laser grooving process at the second thickness T2 is not exposed to the lower surface of the semiconductor substrate 110.

Referring to FIG. 17 and FIG. 18C, a carrier substrate 300 is attached to the lower surface of the ground semiconductor substrate 110, and the protective sheet 200 on the upper surface is removed to expose the upper surface of the device layer 120 so that laser grooving may be performed (S230).

A groove BS may be formed from the upper surface of the exposed device layer 120 along the cutting area 104 to a predetermined depth. In this embodiment, each of the plurality of integrated circuit areas 102 has a quadrangular shape (rectangular or square shape), and when arranged in a plurality of rows and a plurality of columns with the cutting area 104 therebetween, the grooves BS are formed to extend in the row direction and the column direction along the cutting area 104, and the grooves BS extending in the row direction and the column direction may intersect each other near corners of adjacent four integrated circuit areas 102 located in two adjacent rows and two adjacent columns of the integrated circuit areas 102.

A laser having a wavelength that penetrates the semiconductor substrate 110 may be controlled/provided to form a groove BS in a specific region of the semiconductor substrate 110. In this manner, by radiating the laser along the cutting line CL, a groove BS may be formed along the cutting line CL having a certain depth in the semiconductor substrate 110.

The groove BS may have a V-shape when viewed in a vertical cross-section as illustrated in FIG. 2, but is not limited thereto. For example, a V-shaped groove BS symmetrically centered on the cutting line CL in the cutting area 104 between the two integrated circuit areas 102 may be formed so that the width thereof decreases in a direction receding from the upper surface downward. The upper surface width of the groove BS may be equal to or smaller than the width of the cutting area 104. The upper surface width of the groove BS is a width of the groove BS at a level where the upper surface of the device layer 120 is placed.

The groove BS within the area of the cutting area 104 formed through laser grooving may extend to the bending point n1, and a tip may be formed at a bottom of the groove so that a V-shaped groove BS has a bottom end at the bending point n1. The bending point n1 may be disposed at a depth equal to the second height h2 from the upper surface of the semiconductor substrate 110.

In this manner, when the groove BS formed through laser grooving has a tip at the lower end, the width/distance between the inclined surfaces of the groove BS decreases in a direction receding from the upper surface of the device layer 120, and may include a tip n1 without a bottom surface, for example, an intersection that appears as the tip n1. Therefore, the area exposed to the laser may be significantly reduced because there is no bottom surface. Accordingly, when the groove BS is formed through laser grooving, the heat affected zone HAZ, which is a damaged area due to laser heat, may be significantly reduced.

In the laser grooving process, when the laser groove RS is formed in a V-shape extending from the upper surface to the lower surface of the semiconductor wafer 100W, the semiconductor chip 100a of FIGS. 3 and 4 may be manufactured.

Referring to FIG. 17 and FIG. 18D, an ashing process may be performed on the semiconductor wafer 100W (S240).

For example, a reaction gas such as oxygen (O₂), hydrogen (H₂), water vapor (H₂O), nitrogen (N₂), fluorine-based gas such as CF4 and SF6 is formed in a plasma state and provided on the surface of grooves BS, and the heat affected zone HAZ formed on the slope of the groove BS may be removed by reacting the active radical (R) in the plasma with the heat affected zone HAZ on the semiconductor substrate 110.

By performing the plasma ashing process in this manner, the heat affected zone HAZ on the surface of the groove BS may be significantly reduced.

Referring to FIGS. 17 and 18E, the carrier substrate 300 may be extended so that individual semiconductor chips 100 are divided from the semiconductor wafer 100W (S250). By this extension, a crack CR is propagated from the groove BS to the lower surface of the semiconductor substrate 110, and each semiconductor chip 100 may be separated into units along the propagated crack CR. At this time, the carrier substrate 300 may be further extended such that the semiconductor chips 100 remain respective unit chips as shown in FIG. 18E. At this time, as an example, the carrier substrate 300 may be placed on a jig and the jig may be pushed up to expand the carrier substrate 300. For example, the carrier substrate may be bent, which causes the semiconductor wafer 100W to similarly bend, which stretches the semiconductor wafer 100W and causes the cracks to propagate in order to separate the waver 100 W into individual semiconductor chips. The embodiments are not limited to this method, and other techniques may be performed on the carrier substrate 300 and wafer 100W to cause stretching of the wafer 100W. Accordingly, the semiconductor wafer 100W may be divided into individual semiconductor chips 100 by expanding gaps formed by the propagated crack CR along the groove BS.

In this manner, after forming the laser groove RS in a V shape, the heat affected zone HAZ is removed by an ashing process, and then the carrier substrate 300 is expanded to separate the semiconductor chips 100 from each other, thereby providing semiconductor chips 100 each with a significantly-reduced heat affected zone HAZ on a side where the laser groove BS was formed.

FIG. 19 is a cross-sectional view exemplarily illustrating a semiconductor package 10 manufactured according to embodiments.

Referring to FIG. 19, the semiconductor package 10 of an example embodiment may include first semiconductor chips 100A, 100B, 100C and 100D bonded with a direct bonding structure, a second semiconductor chip 500, a molding member/layer 530, and bumps 550 electrically connected to and contact lower pads 544 below the second semiconductor chip 500 and configured to be bonded to the outside. According to an example embodiment, the first semiconductor chips 100A, 100B, 100C and 100D may be provided in more or less numbers than those illustrated in the drawing. For example, three or fewer or five or more first semiconductor chips may be stacked on the second semiconductor chip 500. Each of the first semiconductor chips 100A, 100B, 100C and 100D and the second semiconductor chip 500 may be manufactured through the process described with reference to FIGS. 9 to 18D, and then the first semiconductor chips 100A, 100B, 100C and 100D and the second semiconductor chip 500 may be bonded to each other. Each component (e.g., each of the first and second semiconductor chips) may have characteristics identical to or similar to those described above. The first semiconductor chips 100A, 100B, 100C, and 100D may each include one of the semiconductor chips 100 of FIGS. 1 to 8, and may have an inclined surface at least in a part of a side surface, and may include a groove BS of a step structure by bonding with a lower surface of the semiconductor chip 100 at the side surface because upper surfaces of the first semiconductor chips 100A, 100B, 100C, and 100D have different areas from lower surfaces of the first semiconductor chips 100A, 100B, 100C, and 100D.

The molding member/layer 530 is disposed on the second semiconductor chip 500 and may seal/cover at least portions of the respective first semiconductor chips 100A, 100B, 100C and 100D. As illustrated in FIG. 19, the molding member/layer 530 may be formed to expose the upper surface of the uppermost first semiconductor chip 100d. However, according to an example embodiment, the molding member/layer 530 may also be formed to cover the upper surface of the uppermost first semiconductor chip 100d. The molding member/layer 530 may include, for example, Epoxy Mold Compound EMC, but the material of the molding member/layer 530 is not limited.

For example, the second semiconductor chip 500 may be a buffer chip or a control chip including a plurality of logic elements and/or memory elements in a device layer 501. The second semiconductor chip 500 may transmit signals from the first semiconductor chips 100A, 100B, 100C and 100D stacked thereon to the outside, and may also transmit signals and power from the outside to the first semiconductor chips 100A, 100B, 100C and 100D. The first semiconductor chips 100A, 100B, 100C and 100D may include or may be volatile memory devices such as DRAM, SRAM, or nonvolatile memory devices such as PRAM, MRAM, FeRAM, or RRAM. In this case, the semiconductor package 10 of the present embodiment may be used for High Bandwidth Memory (HBM) products, Electro Data Processing (EDP) products, and the like.

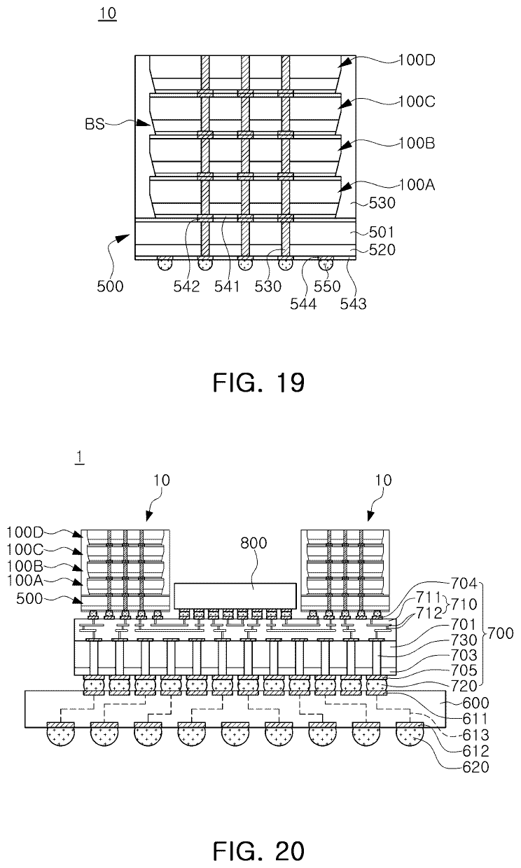

FIG. 20 is a cross-sectional view exemplarily illustrating a semiconductor package 1 manufactured according to embodiments.

Referring to FIG. 20, a semiconductor package 1 of an example embodiment may include a package substrate 600, an interposer substrate 700, and at least one chip structure 10. In addition, the semiconductor package 1 may further include a logic chip or processor chip 800 disposed adjacent to the chip structure 10 on the interposer substrate 700.

The chip structure 10 may be manufactured through the process described with reference to FIGS. 9 to 18E, similar to the semiconductor package 10 described with reference to FIG. 19, and each component may have the same or similar characteristics as those described above. For example, each chip structure 10 of the present embodiment may be the semiconductor package 10 described above with respect to FIG. 19.

The package substrate 600 is a support substrate on which the interposer substrate 700, the logic chip or processor chip 800, and the chip structure 10 are mounted, and may be a substrate for a semiconductor package, including a printed circuit board (PCB), a ceramic substrate, a glass substrate, a tape wiring substrate, or the like. The body of the package substrate 600 may include different materials depending on the type of the substrate. For example, in the case in which the package substrate 600 is a printed circuit board, the body of the package substrate 600 may be a body copper-clad laminate or may have a form in which a wiring layer is additionally stacked on one side or both sides of the copper-clad laminate.

The interposer substrate 700 may include a substrate 701, a lower protective layer 703, a lower pad 705, an interconnection structure 710, a metal bump 720, and a through via 730. The chip structure 10 and the logic chip or processor chip 800 may be stacked on the package substrate 600 via the interposer substrate 700. The interposer substrate 700 may electrically connect the chip structure 10 and the logic chip or processor chip 800 to each other.

The substrate 701 may be formed of, for example, any one of a silicon, organic, plastic, and glass substrate. When the substrate 701 is a silicon substrate, the interposer substrate 700 may be referred to as a silicon interposer and may be manufactured through the process described with reference to FIGS. 9 to 18. Unlike what is illustrated in the drawing, when the substrate 701 is an organic substrate, the interposer substrate 700 may be referred to as a panel interposer.

A lower protective layer 703 may be disposed on the lower surface of the substrate 701, and a lower pad 705 may be disposed on the lower protective layer 703. The lower pad 705 may be electrically connected to and/or contact a through via 730. The chip structure 10 and the logic chip or processor chip 800 may be electrically connected to the package substrate 600 through metal bumps 720 disposed on the lower pad 705.

The interconnection structure 710 may be disposed on the upper surface of the substrate 701 and may include an interlayer insulating layer 711 and a single-layer or multi-layer wiring structure 712. When the interconnection structure 710 is formed of a multilayer wiring structure, wiring patterns of different layers may be electrically connected to each other through contact vias.

The through via 730 may extend from the upper surface of the substrate 701 to the lower surface of the substrate 701 and penetrate the substrate 701. In addition, the through via 730 may extend into the interior of the interconnection structure 710 and be electrically connected to the wiring of the interconnection structure 710. When the substrate 701 is silicon, the through via 730 may be referred to as a TSV. Depending on some example embodiments, the interposer substrate 700 may include the interconnection structure 710 and may not include the through via 730.

The interposer substrate 700 may be used for the purpose of converting or transmitting an input electrical signal between the package substrate 600 and the chip structure 10 or the logic chip or processor chip 800. Therefore, the interposer substrate 700 may not include components such as active components or passive components. In addition, according to the example embodiment, the interconnection structure 710 may be disposed under the through via 730. For example, the positional relationship between the interconnection structure 710 and the through via 730 may be different for different embodiments.

The metal bump 720 may be disposed on the lower surface of the interposer substrate 700 and may be electrically connected to the wiring of the interconnection structure 710. The interposer substrate 700 may be stacked on the package substrate 600 through the metal bump 720. The metal bump 720 may be electrically connected to and/or contact the lower pad 705 and may be electrically connected to the wiring structure 712 of the interconnection structure 710 and through-via 730. In one example, some of the lower pads 705 used for power or ground may be integrated and connected together to a metal bump 720, so that the number of lower pads 705 may be greater than the number of metal bumps 720.

The logic chip or processor chip 800 may include or may be, for example, a central processor (CPU), a graphics processor (GPU), a field programmable gate array (FPGA), a digital signal processor (DSP), an encryption processor, a microprocessor, a microcontroller, an analog-to-digital converter, an application-specific integrated circuit (ASIC), and the like. Depending on the type of elements included in the chip 800, the semiconductor package 1 may be a server-oriented semiconductor package or a mobile-oriented semiconductor package.

The semiconductor package 1 may further include an internal sealant covering the side and upper surface of the chip structure 10 and the logic chip or processor chip 800 on the interposer substrate 700. In certain embodiments, the semiconductor package 1 may further include an external sealant covering the interposer substrate 700 and the internal sealant on the package substrate 600. The external sealant and the internal sealant may be formed together and may not be distinguished in certain embodiments. According to an example embodiment, the semiconductor package 1 may further include a heat sink covering the chip structure 10 and the logic chip or processor chip 800 on the package substrate 600.

As set forth above, according to some example embodiments, by forming laser grooves on sides of a semiconductor substrate so that they are sharp, and separating the semiconductor substrate while significantly reducing a heat affected zone formed by the laser grooving through an ashing process, chip strength and reliability may be improved.

In addition, crack propagation is carried out by laser grooving of semiconductor substrates without a Stealth Dicing Back Grinding (SDBG) or Grinding After Laser (GAL) process, thereby separating chips.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While example embodiments have been illustrated and described above, it will be apparent to those skilled in the art that modifications and variations could be made without departing from the scope of the present inventive concept.

What is claimed is:

1. A method of manufacturing a semiconductor package, comprising:
forming a laser groove at a predetermined depth from a front surface of a semiconductor wafer in a cutting area of the semiconductor wafer;
performing ashing on the laser groove and removing a heat affected zone; and
dividing the semiconductor wafer into individual semiconductor chips by stretching the semiconductor wafer,
wherein the laser groove includes two side surfaces angled from the front surface of the semiconductor wafer and opposing each other, and an intersection of the two side surfaces at a lower end of the laser groove forms a tip.

2. The method of claim 1, further comprising performing grinding on a lower surface of the semiconductor wafer and reducing a thickness of the semiconductor wafer, after removing the heat affected zone.

3. The method of claim 2, wherein each of the side surfaces of the laser groove includes an inclined portion with respect to the front surface of the semiconductor wafer.

4. The method of claim 3, wherein a distance from the tip of the laser groove to the ground lower surface of the semiconductor wafer is smaller than a predetermined depth from the tip to the front surface of the semiconductor wafer.

5. The method of claim 4, wherein the semiconductor wafer includes a semiconductor substrate and a device layer on the semiconductor substrate.

6. The method of claim 5, wherein the front surface of the semiconductor wafer forms a front surface of the device layer such that each of the side surfaces of the laser groove extends from the front surface of the device layer to a first depth of the semiconductor substrate.

7. The method of claim 5, wherein each of the side surfaces of the laser groove includes a first inclined surface exposing the device layer and a second inclined surface exposing the semiconductor substrate, and the first inclined surface and the second inclined surface are continuous.

8. The method of claim 5, wherein the device layer includes integrated circuit areas including semiconductor devices and the cutting area defining and surrounding the integrated circuit areas and extending in a row direction and in a column direction of the integrated circuit areas, and
the laser groove is formed along the cutting area.

9. The method of claim 5, wherein the semiconductor wafer includes through-electrodes penetrating through the semiconductor substrate and electrically connected to the device layer.

10. The method of claim 1, wherein the removing of the heat affected zone includes performing plasma ashing on the laser groove by providing a reaction gas.

11. A method of manufacturing a semiconductor package, comprising:
attaching a protective film to a front surface of a semiconductor wafer, and reducing a thickness of the semiconductor wafer by grinding a back surface of the semiconductor wafer;
removing the protective film from the front surface of the semiconductor wafer, and forming a laser groove at a predetermined depth from the front surface in a cutting area of the semiconductor wafer;
performing ashing on the laser groove and removing a heat affected zone; and
dividing the semiconductor wafer into individual semiconductor chips by stretching the semiconductor wafer,
wherein the laser groove includes two side surfaces extending from the front surface of the semiconductor wafer and opposing each other, and an intersection of the two side surfaces at a lower end of the laser groove forms a tip.

12. The method of claim 11, wherein a distance from the tip of the laser groove to the ground back surface of the semiconductor wafer is less than a predetermined depth from the tip to the front surface of the semiconductor wafer.

13. The method of claim 11, wherein the semiconductor wafer includes a semiconductor substrate and a device layer on the semiconductor substrate.

14. The method of claim 13, wherein the laser groove extends from a front surface of the device layer to a first depth of the semiconductor substrate and includes an inclined portion.

15. The method of claim 13, wherein each of the side surfaces of the laser groove includes a first side surface exposing the device layer and a second side surface exposing the semiconductor substrate, and the first side surface and the second side surface are continuous.

16. The method of claim 14, wherein inclination angles of the second side surfaces of the side surfaces of the laser groove are different from each other.

17. The method of claim 11, wherein the laser groove extends from the front surface of the semiconductor wafer to the back surface of the semiconductor wafer when the back surface is ground.

18. A method of manufacturing a semiconductor package, comprising:
forming a semiconductor wafer by forming a device layer on a semiconductor substrate;
forming a laser groove from a front surface of the device layer to a predetermined depth of the semiconductor substrate in a cutting area of the semiconductor wafer;
performing ashing on the laser groove and removing a heat affected zone; and
dividing the semiconductor wafer into individual semiconductor chips by stretching the semiconductor wafer,
wherein the laser groove includes two side surfaces angled from the front surface of the device layer and opposing each other, and an intersection of the two side surfaces at a lower end of the laser groove forms a tip.

19. The method of claim 18, wherein the device layer includes the front surface and a lower surface, and an inclined side surface between the front surface and the lower surface,
the semiconductor substrate includes a front surface and a lower surface, and a side surface between the front surface and the lower surface when the semiconductor wafer is divided into the individual semiconductor chips,
the side surface of the semiconductor substrate includes a first side surface including an inclined region extending continuous in the same angle with the side surface of the device layer, and a second side surface that is bent from the first side surface, and
the method of manufacturing the semiconductor package further comprises grinding the semiconductor substrate so that a height of the second side surface is smaller than a sum of a height of the device layer and a height of the first side surface.

20. The method of claim 19, wherein, in each of the individual semiconductor chips, horizontal cross-sectional areas of the device layer increase in a direction moving from the front surface to the lower surface of the device layer, and an area of the front surface of the semiconductor substrate is smaller than an area of the lower surface of the semiconductor substrate.
